(19) United States
(12) Patent Application Publication
(10) Pub. No.: US 2013/0098668 A1
(43) Pub. Date: Apr. 25, 2013

(54) CONDUCTIVE SUBTRATE AND METHOD OF MANUFACTURING THE SAME

(71) Applicant: SAMSUNG ELECTRO-MECHANICS CO., LTD., Suwon (KR)

(72) Inventors: Woon Chun Kim, Suwon (KR); Seung Hyun Sohn, Suwon (KR); Kang-Heon Hur, Suwon (KR); Hyun Ho Lim, Suwon (KR)

(73) Assignee: SAMSUNG ELECTRO-MECHANICS CO., LTD., Suwon (KR)

(21) Appl. No.: 13/657,286

(22) Filed: Oct. 22, 2012

(30) Foreign Application Priority Data
Oct. 25, 2011 (KR) 10-2011-0109379

(51) Int. Cl. H05K 1/09; H05K 1/00; B05D 5/12; B44C 1/22; B82Y 99/00; B82Y 40/00

(52) U.S. Cl. 174/257; 427/58; 216/13; 427/123; 427/126.3; 427/122; 174/250; 174/258; 977/734; 977/742; 977/932

(57) ABSTRACT

Disclosed herein is a method of manufacturing a conductive substrate, the method including: a first electrode applying operation of applying first electrodes on a substrate; a first electrode forming operation of forming the first electrodes of fine lines by partly removing the first electrodes; and a second electrode forming operation of forming second electrodes on the substrate from which the first electrodes are removed, thereby enhancing reliability in a whole product including the conductive substrate.

### CROSS REFERENCE(S) TO RELATED APPLICATIONS

This application claims the benefit under 35 U.S.C. Section 119 of Korean Patent Application Serial No. 10-2011-0109379, entitled “Conductive Substrate and Method of Manufacturing the Same” filed on Oct. 25, 2011, which is hereby incorporated by reference in its entirety into this application.

### BACKGROUND OF THE INVENTION

1. Technical Field

The present invention relates to a conductive substrate and a method of manufacturing the same, and more particularly, to a conductive substrate used for a touch screen panel included in an image display apparatuses and a method of manufacturing the same.

2. Description of the Related Art

Recently, touch input devices for sensing a touch, such as touch sensors or touch screens, have been developed as input means for controlling operations of many electric/electronic devices. In particular, touch screen panels are apparatuses for sensing user contact locations on a display screen, and performing control of electric/electronic devices including a control of the display screen by using information regarding the sensed user contact locations as input information.

In conventional touch screen panels, a plurality of first conductive films are generally formed on one surface of a transparent substrate at a certain interval, and a second transparent conductive substrate is formed on a front surface of the transparent substrate on which the plurality of first conductive films are formed.

The conventional touch screen panels are manufactured by forming the plurality of first conductive films on the transparent substrate at a certain interval, attaching an adhesive agent on the plurality of first conductive films, and coating the second conductive film on the front surface of the transparent substrate.

However, the conventional touch screen panels had a problem that a method of coating the second conductive film on the plurality of first conductive films causes an empty space (a void) in a corner part where the second conductive film and the plurality of first conductive films contact each other.

Further, thicknesses of the second conductive film and the plurality of first conductive films formed on the transparent substrate extremely increase, which deteriorates transmissivity of light, and causes a stepped difference.

These problems involved a reduction in reliability of a whole touch screen panel.

Accordingly, a touch screen panel capable of preventing the empty space (the void) and the stepped difference from occurring, and enhancing the transmissivity of light by changing structures of the first and second conductive films formed on the transparent substrate and manufacturing methods thereof is required.

### SUMMARY OF THE INVENTION

An object of the present invention is to provide a conductive substrate capable of preventing an empty space (a void) and a stepped difference from occurring by changing structures of first and second electrodes in such a way that the first electrodes of fine lines are formed on a substrate, and the second electrodes are formed between the first electrodes.

Another object of the present invention is to provide a conductive substrate capable of enhancing transmissivity of light by changing structures of first and second electrodes in such a way that the first electrodes of fine lines are formed on a substrate, and the second electrodes are formed between the first electrodes.

Another object of the present invention is to provide a conductive substrate capable of enhancing reliability of a whole product by changing structures of first and second electrodes in such a way that the first electrodes of fine lines are formed on a substrate, and the second electrodes are formed between the first electrodes.

According to an exemplary embodiment of the present invention, there is provided a method of manufacturing a conductive substrate, the method including: a first electrode applying operation of applying first electrodes on a substrate; a first electrode forming operation of forming the first electrodes of fine lines by partly removing the first electrodes; and a second electrode forming operation of forming second electrodes on the substrate from which the first electrodes are removed.

The first electrode applying operation may include: a resist applying operation of applying a resist having an etched part on the first electrodes; and a first electrode etching operation of forming the first electrodes of fine lines by etching the first electrodes according to the resist having the etched part.

The first electrode applying operation may include applying the first electrodes by using a sputtering method.

The second electrode forming operation may include applying the second electrodes by using one of the sputtering method and a coating method.

The first electrodes of fine lines may have line widths between 1˜10 μm, and have aperture ratios of 90% or higher.

The first electrodes may have a mesh structure.

The first electrodes may be formed of metal materials.

The second electrodes may be formed of one selected from the group consisting of ITO (Indium Tin Oxide), ZnO (Zinc Oxide), IZO (Indium Zinc Oxide), Carbon Nano Tube (CNT), AZO (Al-doped ZnO), conductive polymer (PEDOT:poly(3,4-ethylenedioxythiophene)), silver transparent ink, copper transparent ink, and graphene.

According to another exemplary embodiment of the present invention, there is provided a method of manufacturing a conductive substrate, the method including: a second electrode applying operation of applying second electrodes on a substrate; a second electrode forming operation of partly removing the second electrodes; and a first electrode forming operation of forming first electrodes of fine lines on the substrate from which the second electrodes are removed.

The second electrode forming operation may include: a resist applying operation of applying a resist having an etched part on the second electrodes; and a second electrode etching operation of partly removing the second electrodes by etching the second electrodes according to the resist having the etched part.

The first electrode forming operation may include after the second electrode etching operation is performed, forming the first electrodes on the etched part of the second electrodes by applying the first electrodes on the substrate on which the second electrodes and the resist are sequentially applied.

According to another exemplary embodiment of the present invention, there is provided a conductive substrate including: a substrate; first electrodes of fine lines formed on the substrate; and second electrodes formed on the substrate and between the first electrodes.

The first electrodes of fine lines may have line widths between 1˜10 μm, and have aperture ratios of 90% or higher.

The first electrodes may have a mesh structure.

The first electrodes may be formed of metal materials.

The second electrodes may be formed of one selected from the group consisting of ITO, ZnO, IZO, CNT, AZO, conductive polymer (PEDOT:poly(3,4-ethylenedioxythiophene)), silver transparent ink, copper transparent ink, and graphene.

The substrate may be formed of a transparent material and one selected from the group consisting of polyethylene, polypropylene, acryl, glass, and polyethylene terephthalate (PET).

### BRIEF DESCRIPTION OF THE DRAWINGS

FIG. 1 is a cross-sectional view of a conductive substrate according to an embodiment of the present invention;

FIG. 2 is a plan view of the conductive substrate of FIG. 1;

FIGS. 3 through 7 are cross-sectional views for explaining a method of manufacturing a conductive substrate according to an embodiment of the present invention; and

FIGS. 8 through 12 are cross-sectional views for explaining a method of manufacturing a conductive substrate according to another embodiment of the present invention.

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, the embodiments of the present invention will now be described in detail with reference to the accompanying drawings.

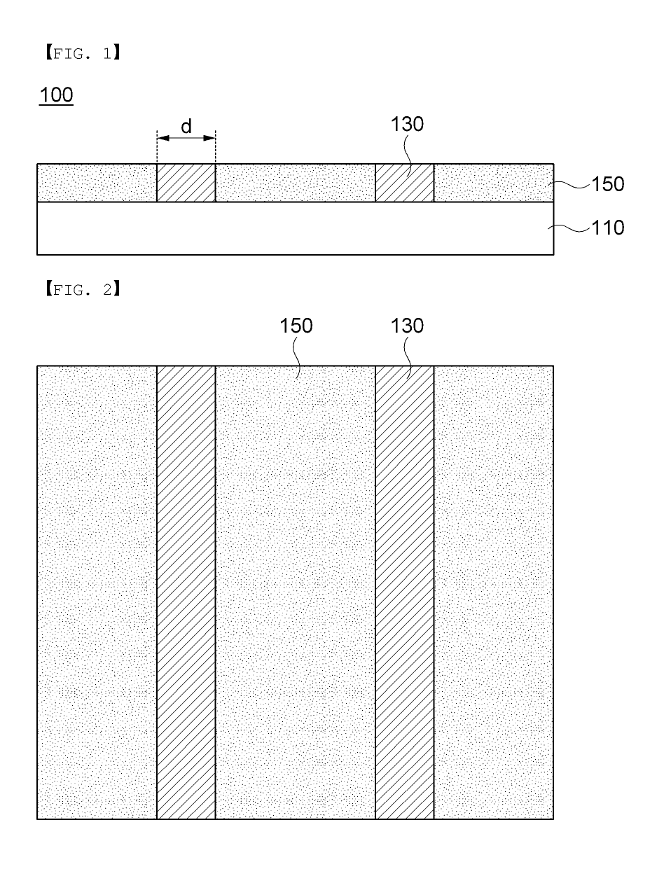

FIG. 1 is a cross-sectional view of a conductive substrate 100 according to an embodiment of the present invention, and FIG. 2 is a plan view of the conductive substrate 100 of FIG. 1.

Referring to FIGS. 1 and 2, the conductive substrate 100 includes a substrate 110, a plurality of first electrodes 130, and a plurality of second electrodes 150.

The conductive substrate 100 may be used for a touch screen panel (TSP) included in an image display apparatus, etc. The TSP refers to an apparatus for inputting a user's command by selecting an indication displayed on a screen of the image display apparatus by using a person's finger or an object.

To this end, the TSP is included in a front face of the image display apparatus, converts a contact location where the person's finger or the object contacts into an electrical signal, and accordingly receives an indication selected in the contact location as an input signal. The TSP is connected to the image display apparatus such as a key board and a mouse and replaces an additional input apparatus, and thus its application range of the TSP is increasing.

A capacitive TSP method, a resistive film TSP method, and an optical sensing TSP method, etc. are known as methods of realizing the TSP described above. Among the above methods, the capacitive TSP method senses a change in capacitance formed by a conductive sensing pattern with another neighboring sensing pattern or a ground electrode, etc. when the person's finger or the object contacts the TSP, and converts the contact location into the electrical signal, and thus is most generally used.

A substrate used in the TSP described above will now be in more detail described.

The substrate 110 may be a transparent substrate formed of an insulating transparent material. For example, the transparent substrate may be formed of a plastic material, such as polyethylene, polypropylene, acryloyl or polyethylene terephthalate (PET), etc. However, the transparent substrate is not limited thereto and may be formed of various materials such as glass.

If the substrate 110 is applied to a touch screen, the substrate 110 may enhance sensitivity of a touch screen pad, and may be formed in a thin sheet between about 100 and about 150 μm in such a way that an intensity of light irradiated from a display does not deteriorate.

The first electrodes 130 may be formed on the substrate 110 of fine lines (first lines), and may be arrange in plural at a certain interval. In this regard, the first electrodes 130 may have a grid structure or a mesh structure.

The first electrodes 130 may be formed of a metal material, for example, silver (Ag), copper (Cu), gold (Au), aluminum (Al), iron (Fe), titanium (Ti) or molybdenum (Mo), etc. However, the first electrodes 130 are not limited thereto and may be formed of various materials.

The first electrodes 130 may have a relatively smaller surface resistance and lower transmissivity than the second electrodes 150. However, since the first electrodes 130 may have line widths d between 1˜10 μm, and aperture ratios of 90% or higher, although the transmissivity of the first electrodes 130 are relatively lower than that of the second electrodes 150, the transmissivity of a whole product is not influenced.

A sputtering method may be used to form the first electrodes 130. The sputtering method is a technology of attaching a film to a surface of an object and may be used to form a thin film or a thick film in ceramic or a semiconductor material, etc. by evaporating a solid in a high vacuum status in order to manufacture an electronic circuit.

To be more specific, the sputtering method may be referred to as a sputtering deposition method, and may form a thin film by attaching atoms that are materials of the thin film to a surface of an object. That is, if ionized atoms (Ar) are accelerated by an electric field and collide with materials of a thin film, atoms of the materials of the thin film are bounced due to the collision and are attached to the surface of the object and thus the thin film is formed. In addition to the sputtering deposition method, various methods such as a thin film deposition method using evaporation may be used to form the first electrodes 130. The thin film deposition method using evaporation heats a boat using an electronic beam or an electric filament in a high vacuum status (5×10-5˜1×10-7 torr), melts and evaporates a metal on the boat so as to deposit a metal material. In this regard, the evaporated metal is condensed on a surface of a cold object, and thus the thin film is formed.

The second electrodes 150 are formed on the substrate 110 and between the first electrodes 130. More specifically, the second electrodes 150 are formed on the substrate 110 on which the first electrodes 130 are not formed, i.e. are filled in remaining parts of the first electrodes 130, thereby preventing an empty space (a void) and a stepped difference from occurring in the substrate 110.

The second electrodes 150 may have a relatively greater surface resistance and higher transmissivity than the first electrodes 130, and be formed of transparent conductive materials. For example, the second electrodes 150 may be formed of ITO (Indium Tin Oxide), ZnO (Zinc Oxide), IZO (Indium Zinc Oxide), Carbon Nano Tube (CNT), AZO (Al-doped ZnO), conductive polymer (PEDOT:poly(3,4-ethylenedioxythiophene)), silver transparent ink, copper transparent ink, graphene, etc. However, the second electrodes 150 are not limited thereto and may be formed of various materials. In this regard, graphene refers to a basic material of fullerene (C60), CNT, and graphite having a plane structure including carbon atoms having a thickness of one atom.

One of the sputtering method and a coating method may be used to form the second electrodes 150. As described above, the sputtering method is a technology of attaching a film to a surface of an object and may be used to form a thin film or a thick film in ceramic or a semiconductor material, etc. by evaporating a solid in a high vacuum status in order to manufacture an electronic circuit. The coating method enhances a surface quality of a target object by covering the surface of the target object that is a background with a thin film such as a metal different from the target object or ceramic, etc. In more detail, the coating method is divided into a physical deposition method and a chemical deposition method.

A method of manufacturing a conductive substrate according to an embodiment of the present invention will now be described below.

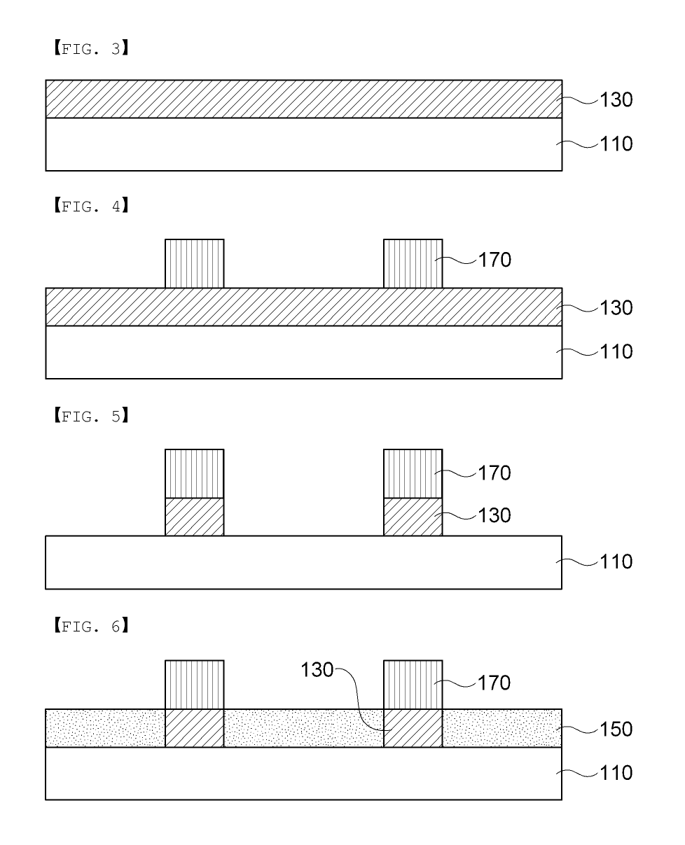

FIGS. 3 through 7 are cross-sectional views for explaining a method of manufacturing a conductive substrate according to an embodiment of the present invention. Referring to FIG. 3, the first electrodes 130 are applied on the substrate 110. The substrate 110 may be a transparent substrate formed of an insulating transparent material. For example, the transparent substrate may be formed of a plastic material, such as polyethylene, polypropylene, acryl or PET, etc. However, the transparent substrate is not limited thereto and may be formed of various materials such as glass.

If the substrate 110 is applied to a touch screen, the substrate 110 may enhance sensitivity of a touch screen pad, and may be formed in a thin sheet between about 100 and about 150 μm in such a way that an intensity of light irradiated from a display does not deteriorate.

In this regard, a sputtering method may be used to form the first electrodes 130. The sputtering method is a technology of attaching a film to a surface of an object and may be used to form a thin film or a thick film in ceramic or a semiconductor material, etc. by evaporating a solid in a high vacuum status in order to manufacture an electronic circuit.

To be more specific, the sputtering method may be referred to as a sputtering deposition method, and may form a thin film by attaching atoms that are materials of the thin film to a surface of an object. That is, if ionized atoms (Ar) are accelerated by an electric field and collide with materials of a thin film, atoms of the materials of the thin film are bounced due to the collision and are attached to the surface of the object and thus the thin film is formed. In addition to the sputtering deposition method, various methods such as a thin film deposition method using evaporation may be used to form the first electrodes 130. The thin film deposition method using evaporation heats a boat using an electronic beam or an electric filament in a high vacuum status (5×10-5˜1×10-7 torr), melts and evaporates a metal on the boat so as to deposit a metal material. In this regard, the evaporated metal is condensed on a surface of a cold object, and thus the thin film is formed.

Thereafter, referring to FIG. 4, a resist 170 having an etched part is applied on the first electrodes 130.

In this regard, the resist 170 may be formed of various photosensitive materials such as a photo resist, a photo solder resist, a dry film, a mask, etc. However, the resist 170 is not limited thereto and may be formed of various materials.

The resist 170 may be formed in such a way that a region corresponding to a location in which the second electrodes 150 are to be formed is opened.

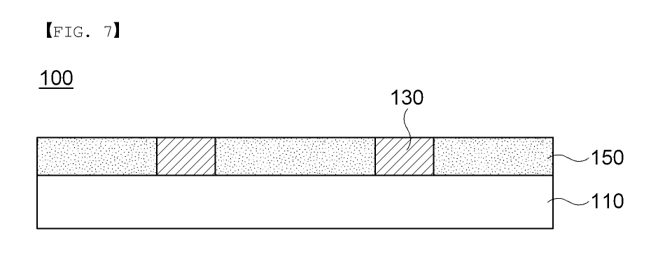

Thereafter, referring to FIG. 5, the first electrodes 130 on fine lines (first lines) are formed by etching the first electrodes 130 according to the resist 170 having the etched part.

In this regard, the first electrodes 130 may be arrange in plural at a certain interval, and have a grid structure or a mesh structure.

The first electrodes 130 may be formed of a metal material, for example, silver (Ag), copper (Cu), gold (Au), aluminum (Al), iron (Fe), titanium (Ti) or molybdenum (Mo), etc. However, the first electrodes 130 are not limited thereto and may be formed of various materials.

The first electrodes 130 may have a relatively smaller surface resistance and lower transmissivity than the second electrodes 150. However, since the first electrodes 130 may have line widths d between 1˜10 μm, and aperture ratios of 90% or higher, although the transmissivity of the first electrodes 130 are relatively lower than that of the second electrodes 150, the transmissivity of a whole product is not influenced.

Thereafter, referring to FIG. 6, the second electrodes 150 are applied on the substrate 110 from which the first electrodes 130 are removed. Referring to FIG. 7, the second electrodes 150 may be formed on the substrate 110 between the first electrodes 130 by removing the resist 170.

In this regard, the second electrodes 150 are formed on the substrate 110 on which the first electrodes 130 are not formed, i.e. are filled in remaining parts of the first electrodes 130, thereby preventing an empty space (a void) and a stepped difference from occurring in the substrate 110.

The second electrodes 150 may be formed of transparent conductive materials. For example, the second electrodes 150 may be formed of ITO, ZnO, IZO, CNT, AZO, conductive polymer (PEDOT: poly(3,4-ethylenedioxythiophene)), silver transparent ink, copper transparent ink, graphene, etc. However, the second electrodes 150 are not limited thereto and may be formed of various materials. In this regard, graphene refers to a basic material of fullerene (C60), CNT, and graphite having a plane structure including carbon atoms having a thickness of one atom.

One of the sputtering method and a coating method may be used to form the second electrodes 150. As described above, the sputtering method is a technology of attaching a film to a surface of an object and may be used to form a thin film or a thick film in ceramic or a semiconductor material, etc. by evaporating a solid in a high vacuum status in order to manufacture an electronic circuit. The coating method enhances a surface quality of a target object by covering the surface of the target object that is a background with a thin film such as a metal different from the target object or ceramic, etc. In more detail, the coating method is divided into a physical deposition method and a chemical deposition method.

A method of manufacturing a conductive substrate according to another embodiment of the present invention will now be described below.

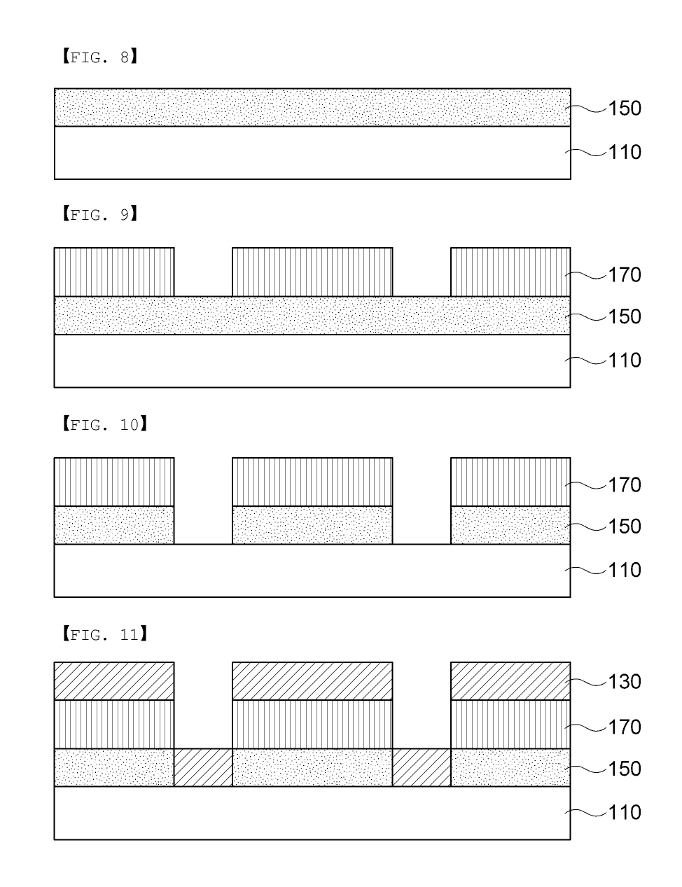

FIGS. 8 through 12 are cross-sectional views for explaining a method of manufacturing a conductive substrate according to another embodiment of the present invention. The redundant descriptions regarding the conductive substrate described with reference to FIGS. 1 and 2 are omitted here.

Referring to FIG. 8, the second electrodes 150 are applied on the substrate 110.

Thereafter, referring to FIG. 9, the resist 170 having an etched part is applied on the second electrodes 150.

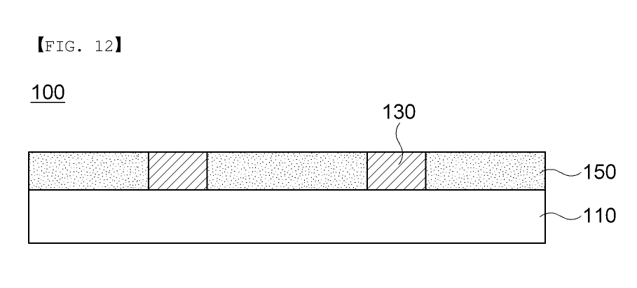

Thereafter, referring to FIG. 10, the second electrodes 150 are partly removed by etching the second electrodes 150 according to the resist 170 having the etched part.

Thereafter, referring to FIG. 11, the first electrodes 130 are formed in the etched part of the second electrodes 150 by applying the first electrodes 130 on the substrate 110 on which the second electrodes 150 and the resist 170 are sequentially applied.

Thereafter, referring to FIG. 12, the first electrodes 130 on fine lines (first lines) are formed by removing the resist 170 and the first electrodes 130 applied on the resist 170.

As described above, structures and manufacturing methods of first and second electrodes are changed in such a way that the first electrodes of fine lines are formed on a substrate, and the second electrodes are formed on the substrate between the first electrodes, thereby preventing an empty space (a void) and a stepped difference from occurring in the substrate, and enhancing transmissivity of light.

Accordingly, reliability of a whole product including a conductive substrate can be enhanced.

As described above, a conductive substrate and a method of manufacturing the conductive substrate according to the embodiments of the present invention can prevent an empty space (a void) and a stepped difference from occurring by changing structures of first and second electrodes and manufacturing methods thereof in such a way that the first electrodes of fine lines are formed on a substrate, and the second electrodes are formed between the first electrodes.

Further, transmissivity of light can be enhanced.

Accordingly, reliability of a whole product including the conductive substrate can be enhanced.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A method of manufacturing a conductive substrate, the method comprising:
a first electrode applying operation of applying first electrodes on a substrate;
a first electrode forming operation of forming the first electrodes of fine lines by partly removing the first electrodes; and
a second electrode forming operation of forming second electrodes on the substrate from which the first electrodes are removed.

2. The method according to claim 1, wherein the first electrode applying operation includes:
a resist applying operation of applying a resist having an etched part on the first electrodes; and
a first electrode etching operation of forming the first electrodes of fine lines by etching the first electrodes according to the resist having the etched part.

3. The method according to claim 1, wherein the first electrode applying operation includes applying the first electrodes by using a sputtering method.

4. The method according to claim 1, wherein the second electrode forming operation includes applying the second electrodes by using one of the sputtering method and a coating method.

5. The method according to claim 1, wherein the first electrodes of fine lines have line widths between 1˜10 μm.

6. The method according to claim 1, wherein the first electrodes of fine lines have aperture ratios of 90% or higher.

7. The method according to claim 1, wherein the first electrodes have a mesh structure.

8. The method according to claim 1, wherein the first electrodes are formed of metal materials.

9. The method according to claim 1, wherein the second electrodes are formed of one selected from the group consisting of ITO (Indium Tin Oxide), ZnO (Zinc Oxide), IZO (Indium Zinc Oxide), Carbon Nano Tube (CNT), AZO (Al-doped ZnO), conductive polymer (PEDOT:poly(3,4-ethylenedioxythiophene)), silver transparent ink, copper transparent ink, and graphene.

10. A method of manufacturing a conductive substrate, the method comprising:
a second electrode applying operation of applying second electrodes on a substrate;
a second electrode forming operation of partly removing the second electrodes; and
a first electrode forming operation of forming first electrodes of fine lines on the substrate from which the second electrodes are removed.

11. The method according to claim 10, wherein the second electrode forming operation includes:
a resist applying operation of applying a resist having an etched part on the second electrodes; and
a second electrode etching operation of partly removing the second electrodes by etching the second electrodes according to the resist having the etched part.

12. The method according to claim 11, wherein the first electrode forming operation includes, after the second electrode etching operation is performed, forming the first electrodes on the etched part of the second electrodes by applying the first electrodes on the substrate on which the second electrodes and the resist are sequentially applied.

13. A conductive substrate comprising:
a substrate;
first electrodes of fine lines formed on the substrate; and
second electrodes formed on the substrate and between the first electrodes.

14. The conductive substrate according to claim 13, wherein the first electrodes of fine lines have line widths between 1˜10 μm.

15. The conductive substrate according to claim 13, wherein the first electrodes of fine lines have aperture ratios of 90% or higher.

16. The conductive substrate according to claim 13, wherein the first electrodes have a mesh structure.

17. The conductive substrate according to claim 13, wherein the first electrodes are formed of metal materials.

18. The conductive substrate according to claim 13, wherein the second electrodes are formed of one selected from the group consisting of ITO, ZnO, IZO, CNT, AZO, conductive polymer (PEDOT:poly(3,4-ethylenedioxythiophene)), silver transparent ink, copper transparent ink, and graphene.

19. The conductive substrate according to claim 13, wherein the substrate is formed of a transparent material and one selected from the group consisting of polyethylene, polypropylene, acryl, glass, and polyethylene terephthalate (PET).
